(19) United States
(12) Patent Application Publication
(10) Pub. No.: US 2006/0094193 A1
(43) Pub. Date: May 4, 2006

(54) Semiconductor device including semiconductor regions having differently strained channel regions and a method of manufacturing the same

(76) Inventors: Manfred Horstmann, Duerrroehrsdorf-Dittersbach (DE); Ekkehard Pruefer, Dresden (DE); Wolfgang Buchholtz, Radebeul (DE)

Correspondence Address: WILLIAMS, MORGAN & AMERSON, 10333 RICHMOND, SUITE 1100, HOUSTON, TX, 77042, US

(21) Appl. No.: 11/145,697

(22) Filed: Jun. 6, 2005

(30) Foreign Application Priority Data
Oct. 29, 2004 (DE) 10 2004 052 617.6

(51) Int. Cl. H01L 21/8234; H01L 21/336; H01L 21/8238

(52) U.S. Cl. 438/299; 438/229; 438/291; 438/197

(57) ABSTRACT

By locally modifying the intrinsic stress of a dielectric layer laterally enclosing gate electrode structures of a transistor configuration formed in accordance with in-laid gate techniques, the charge carrier mobility of different transistor elements may individually be adjusted. In particular, in in-laid gate structure transistor architecture, NMOS transistors and PMOS transistors may receive a tensile and a compressive stress, respectively.

### BACKGROUND OF THE INVENTION

1. Field of the Invention

Generally, the present invention relates to the formation of integrated circuits, and, more particularly, to the formation of semiconductor regions of increased charge carrier mobility, such as a channel region of a field effect transistor, by creating strain in the semiconductor region.

2. Description of the Related Art

The fabrication of integrated circuits requires the formation of a large number of circuit elements on a given chip area according to a specified circuit layout. For this purpose, substantially crystalline semiconductor regions with or without additional dopant materials are defined at specified substrate locations to act as “active” regions, that is, to act, at least temporarily, as conductive areas. Generally, a plurality of process technologies are currently practiced, wherein for complex circuitry, such as microprocessors, storage chips and the like, MOS technology is currently the most promising approach, due to the superior characteristics in view of operating speed and/or power consumption and/or cost efficiency. During the fabrication of complex integrated circuits using MOS technology, millions of transistors, i.e., N-channel transistors and/or P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with a slightly doped or non-doped channel region disposed between the drain region and the source region. The conductivity of the channel region, i.e., the drive current capability of the conductive channel, is controlled by a gate electrode formed adjacent to the channel region and separated therefrom by a thin insulating layer. The conductivity of the channel region upon formation of a conductive channel due to the application of an appropriate control voltage to the gate electrode, depends on the dopant concentration, the mobility of the charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially affects the performance of the MOS transistors. Thus, as the speed of creating the channel, i.e., the conductivity of the gate electrode, and the channel resistivity substantially determine the transistor characteristics, the reduction of the channel length, and associated therewith the reduction of channel resistivity and increase of gate resistivity, renders the channel length a dominant design criterion for accomplishing an increase in the operating speed of the integrated circuits.

The continuing shrinkage of the transistor dimensions, however, entails a plurality of issues associated therewith that have to be addressed so as to not unduly offset the advantages obtained by steadily decreasing the channel length of MOS transistors. One major problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control, as reducing the channel length also requires reducing the depth of the drain and source regions with respect to the interface formed by the gate insulation layer and the channel region, thereby requiring sophisticated implantation techniques. According to other approaches, epitaxially grown regions are formed with a specified offset to the gate electrode, which are referred to as raised drain and source regions, to provide increased conductivity of the raised drain and source regions, while at the same time maintaining a shallow PN junction with respect to the gate insulation layer.

In other conventional solutions, the problem of increased resistivity of polysilicon gate electrodes in extremely scaled devices is addressed by replacing the currently used doped polysilicon by a metal as the gate electrode material, while nevertheless maintaining a self-aligned process sequence for the formation of the drain and source regions and the gate electrode. This may be accomplished by forming a dummy gate which may, in combination with removable sidewall spacers, act as an implantation mask during the formation of the drain and source regions. After embedding the dummy gate in an interlayer dielectric, the dummy gate may be replaced by a highly conductive gate material, such as a metal. With this approach of an “in-laid” gate electrode, the transistor performance may significantly be improved. The problem of restricted channel conductivity, however, is not addressed by this approach.

Furthermore, since the continuous size reduction of the critical dimensions, i.e., the gate length of the transistors, necessitates the adaptation and possibly the new development of highly complex process techniques concerning the above-identified process steps, it has been proposed to also enhance device performance of the transistor elements by increasing the charge carrier mobility in the channel region for a given channel length, thereby offering the potential for achieving a performance improvement that is comparable with the advance to a future technology node of down-sized devices while avoiding many of the above process adaptations associated with device scaling. In principle, at least two mechanisms may be used, in combination or separately, to increase the mobility of the charge carriers in the channel region. First, the dopant concentration within the channel region may be reduced, thereby reducing scattering events for the charge carriers and thus increasing the conductivity. However, reducing the dopant concentration in the channel region significantly affects the threshold voltage of the transistor device, thereby presently making a reduction of the dopant concentration a less attractive approach unless other mechanisms are developed to adjust a desired threshold voltage. Second, the lattice structure in the channel region may be modified, for instance by creating tensile or compressive stress to produce a corresponding strain in the channel region, which results in a modified mobility for electrons and holes, respectively. For example, creating tensile strain in the channel region increases the mobility of electrons, wherein, depending on the magnitude and direction of the tensile strain, an increase in mobility of up to 120% or more may be obtained, which, in turn, may directly translate into a corresponding increase in the conductivity. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor, which may enable the fabrication of fast powerful semiconductor devices without requiring expensive semiconductor materials and manufacturing techniques.

Consequently, it has been proposed to introduce, for instance, a silicon/germanium layer or a silicon/carbon layer in or below the channel region to create tensile or compressive stress that may result in a corresponding strain. Although the transistor performance may be considerably enhanced by the introduction of stress-creating layers in or below the channel region, significant efforts have to be made to implement the formation of corresponding stress layers into the conventional and well-approved MOS technique. For instance, additional epitaxial growth techniques have to be developed and implemented into the process flow to form the germanium- or carbon-containing stress layers at appropriate locations in or below the channel region. Hence, process complexity is significantly increased, thereby also increasing production costs and the potential for a reduction in production yield.

In view of the above-described situation, there exists a need for an alternative technique that enables the creation of different desired stress conditions in different semiconductor regions, while providing the potential for the formation of improved transistor architectures including the introduction of highly conductive gate electrodes.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the combination of the process strategies having the potential for forming enhanced transistor architectures, such as transistor elements including so-called “in-laid” gate electrodes, with enhanced stress or strain engineering to provide at least two different magnitudes or types of strain in two different semiconductor regions. Consequently, different regions within a die area or across the entire substrate bearing a plurality of individual die areas may receive differently strained semiconductor regions to individually adapt the charge carrier mobility and thus the conductivity thereof to specified process and device requirements. In particular, different types of transistors, such as N-type or N-channel transistors and P-type or P-channel transistors, may receive a different type or a different magnitude of strain within the respective channel regions while at the same time the gate conductivity may be enhanced, if desired, due to the possibility of forming in-laid gate electrode structures on the basis of highly conductive materials, such as metals.

According to one illustrative embodiment of the present invention, a method comprises forming a first place holder structure above a first semiconductor region formed in a semiconductor layer that is located on a substrate. A second place holder structure is formed above a second semiconductor region which is formed in the semiconductor layer, and a dielectric layer having a specified intrinsic stress is deposited above the semiconductor layer to enclose the first and second place holder structures. Additionally, a portion of the dielectric layer enclosing the second place holder structure is modified to change the intrinsic stress within the portion. Finally, the first and second place holder structures are replaced by a conductive material.

According to another illustrative embodiment of the present invention, a method comprises forming a first place holder structure above a first channel region of a first transistor and forming a second place holder structure above a second channel region of a second transistor. Moreover, first drain and source regions are formed adjacent to the first channel region and second drain and source regions are formed adjacent to the second channel region. Furthermore, above the first drain and source regions, a first dielectric layer having a first intrinsic stress is formed, and, above the second drain and source regions, a second dielectric layer having a second intrinsic stress that differs from the first intrinsic stress is formed. Finally, the first place holder structure is replaced with a first gate electrode structure and the second place holder structure is replaced with a second gate electrode structure.

According to yet another illustrative embodiment of the present invention, a semiconductor device comprises a first transistor element having a first gate electrode with a first height and a second transistor element having a second gate electrode with a second height. The device further comprises a first dielectric layer having a first intrinsic stress and laterally enclosing the first gate electrode, wherein the first intrinsic stress acts substantially homogenously within the first dielectric layer up to the first height. Moreover, the device comprises a second dielectric layer having a second intrinsic stress and, laterally enclosing the second gate electrode, wherein the second intrinsic stress differs from the first intrinsic stress and acts substantially homogenously within the second dielectric layer up to the second height.

### BRIEF DESCRIPTION OF THE DRAWINGS

The invention may be understood by reference to the following description taken in conjunction with the accompanying drawings, in which like reference numerals identify like elements, and in which:

FIGS. 1a-1h schematically show cross-sectional views of a semiconductor device during various manufacturing stages, wherein different strain is created at different semiconductor regions by means of respective stress layers formed in the vicinity of the semiconductor regions in accordance with a process strategy that enables the formation of in-laid gate electrode structures;

FIG. 2 schematically depicts a semiconductor device in cross-sectional view during a manufacturing stage in which an intrinsic stress of a stress layer is locally modified in accordance with further illustrative embodiments; and

FIGS. 3a and 3b schematically show a semiconductor device in cross-section in a manufacturing stage during which ion species are deposited at certain locations to enhance the stress transfer into respective semiconductor regions in accordance with further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the concept that strain in a semiconductor region, such as a channel region of a transistor element, may highly efficiently be generated by a material layer having a specified intrinsic stress that is formed close to the semiconductor region of interest. By providing a process strategy that allows an effective local adjustment of strain within a die area or within different substrate areas including a plurality of die areas and even at a very small scale, such as at different channel regions of a complementary transistor pair, an enhanced strain engineering may be combined with an enhanced transistor architecture, thereby providing high gate conductivity in combination with high charge carrier mobility and thus channel conductivity even for highly scaled transistor devices. With reference to the accompanying drawings, further illustrative embodiments of the present invention will now be described in more detail.

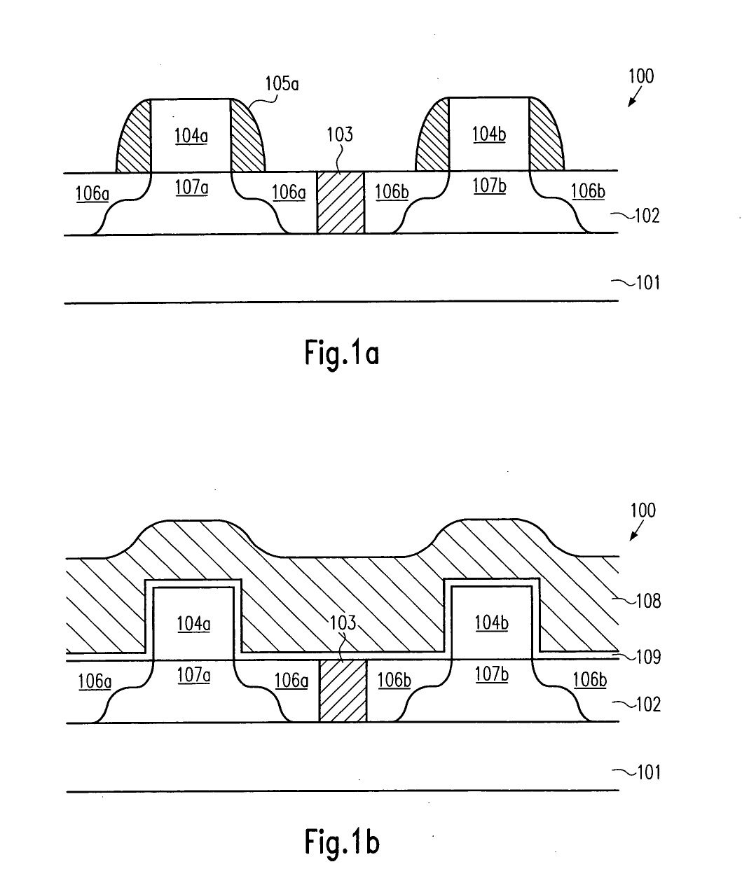

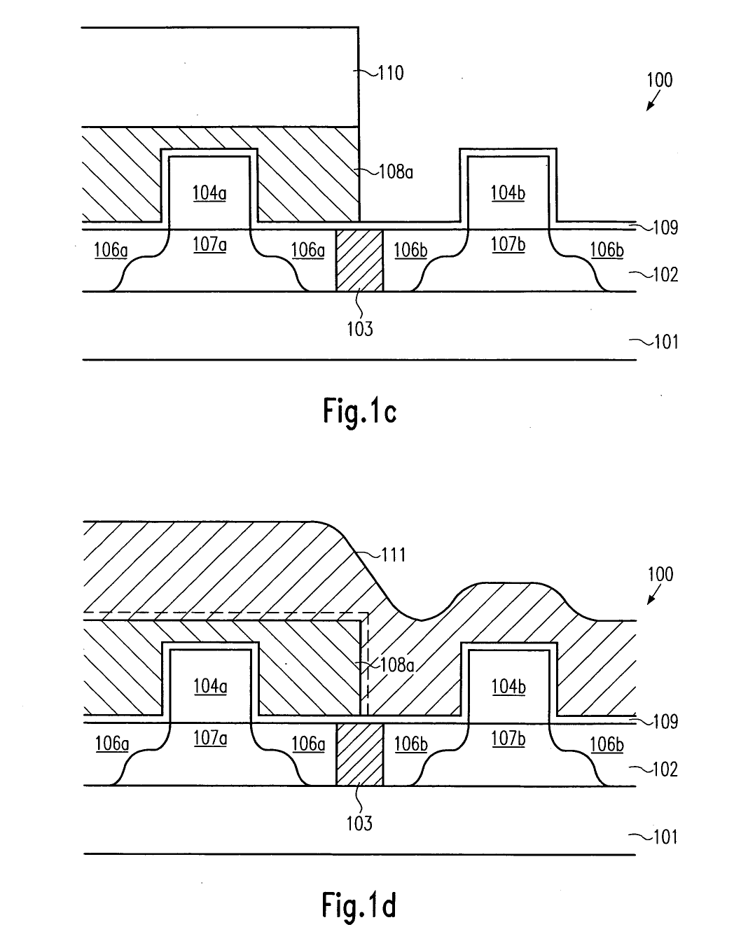

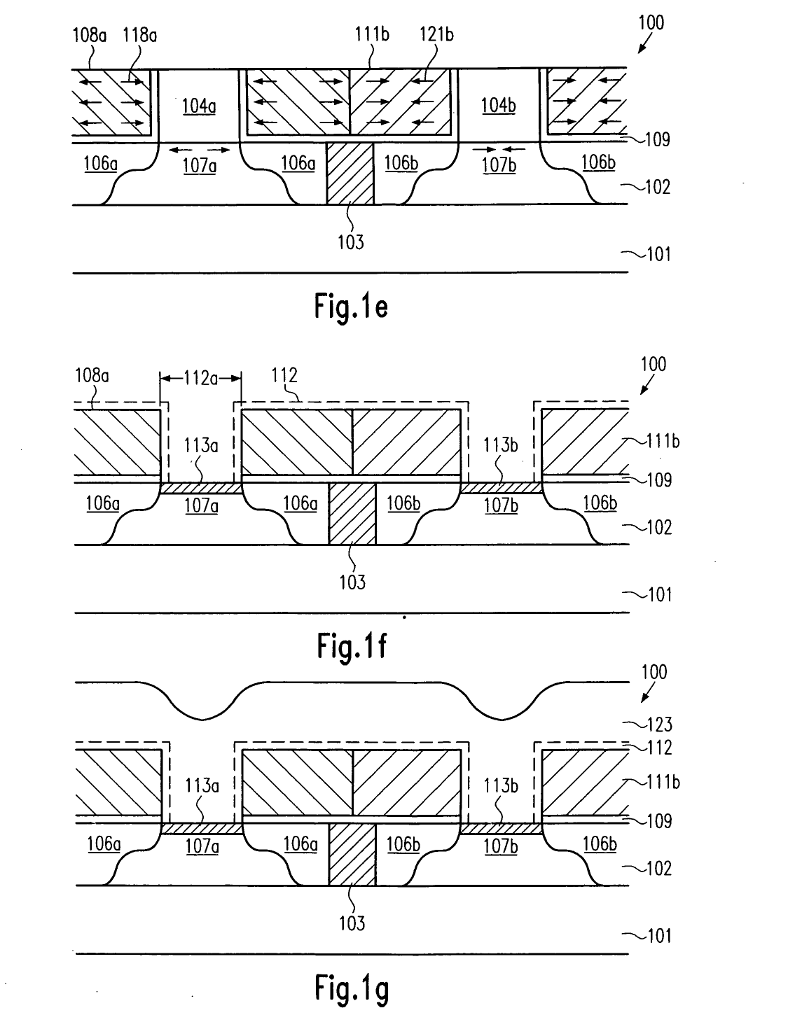

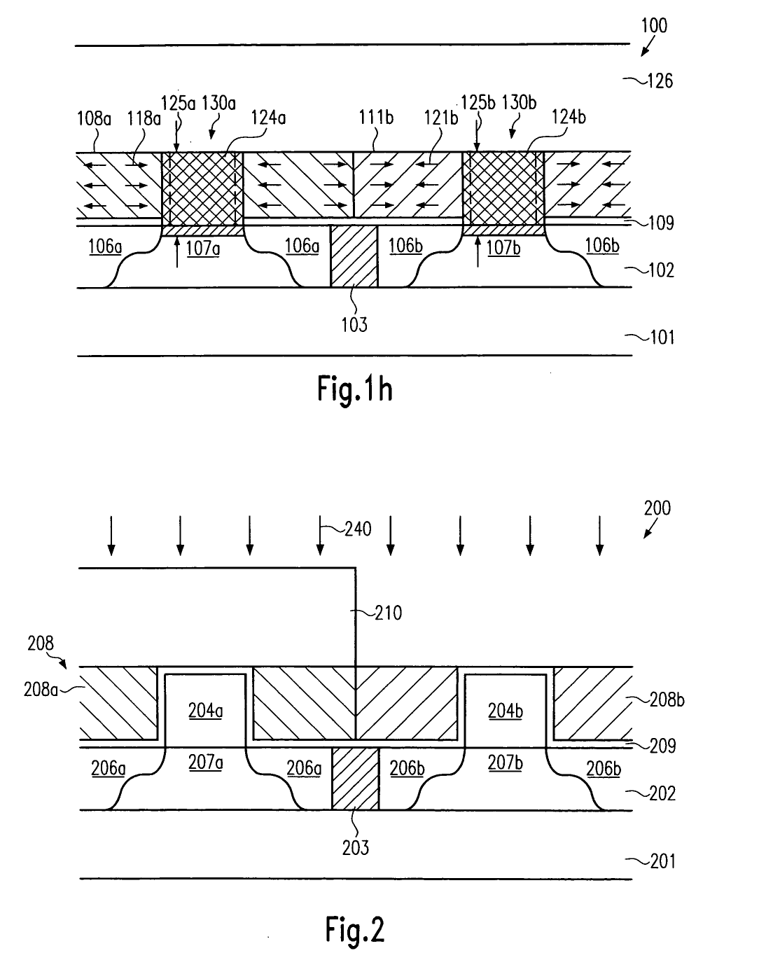

FIG. 1a schematically shows a cross-sectional view of a semiconductor device 100 that comprises a substrate 101, which may represent any appropriate substrate for forming thereon circuit elements of integrated circuits such as microprocessors, storage chips and the like. The substrate 101 may represent a bulk semiconductor substrate, such as a silicon substrate, or may represent, in particular embodiments, a silicon-on-insulator (SOI) substrate, wherein a semiconductor layer 102 may represent the crystalline silicon layer formed on an insulating layer (not shown) within the substrate 101. Since the vast majority of advanced integrated circuits fabricated in accordance with MOS techniques are fabricated on the basis of silicon, in the following detailed description it may frequently be referred to silicon with respect to the semiconductor layer 102, wherein it should be appreciated that any other suitable semiconductor materials, such as gallium arsenide, germanium, silicon/germanium, or any other III-V or II-VI semiconductor materials, may also be used with the present invention. Similarly, the semiconductor layer 102 may represent an upper portion of a bulk semiconductor substrate, although it is shown as a separate layer.

The semiconductor device 100 comprises a first place holder structure 104a formed of any appropriate material, such as silicon dioxide, amorphous carbon, and the like. The first place holder structure 104a is formed above a first semiconductor region 107a, which may represent a first channel region, if a transistor is to be formed by means of the first place holder 104a. First doped regions 106a, which may be arranged symmetrically or asymmetrically with respect to the first semiconductor region 107a, may be formed within the layer 102 and may be provided, in the embodiment shown, in the form of drain and source regions. That is, the vertical and lateral dopant profile of the first doped regions 106a may be designed in accordance with device requirements of a specified transistor type. Hence, in particular embodiments, the doped regions 106a represent first drain and source regions having included therein a dopant material that imparts a specified type of conductivity to these regions. In this embodiment, the regions 106a may be N-doped and the regions 106a in combination with the first semiconductor region 107a may have the characteristics of an N-channel transistor. Moreover, sidewall spacers 105a are formed on sidewalls of the first place holder 104a, wherein the sidewall spacer 105a may differ in material composition from the first place holder 104a to exhibit, in particular embodiments, a desired high etch selectivity in subsequent etch procedures. For example, the sidewall spacer 105a may be comprised of amorphous carbon, silicon nitride, silicon dioxide and the like.

Similarly, a second place holder structure 104b may be formed above a second semiconductor region 107b, which may, in some embodiments, represent the channel region of a second transistor element. Moreover, doped regions 106b may be formed adjacent to the second semiconductor region 107b to define, in particular embodiments, the drain and source regions and the channel region of a specified transistor type. For example, the second semiconductor region 107b enclosed by the doped regions 106b may be located next to the first semiconductor region 107a enclosed by the respective doped regions 106a, but separated therefrom by an isolation structure 103 which may be provided in the form of a trench isolation structure as is typically used in advanced semiconductor devices. When representing a transistor configuration, the regions 107b, 106b may be of the same type as the regions 107a, 106a or may represent a different type of transistor, such as a P-type or P-channel transistor. It should be appreciated, however, that the first and second semiconductor regions 107a, 107b may represent circuit elements that are located at very different positions within the same die area, but which require to receive a different type or magnitude of strain to provide different electrical characteristics. Similarly, the regions 107a, 107b may represent different circuit elements or even different die portions located at different substrate regions, such as a center region and a peripheral region, wherein the strain engineering for the first and second semiconductor regions 107a, 107b may provide more uniform electrical behavior of semiconductor devices fabricated on the central and peripheral regions of the substrate 101. Regarding the material composition of the second place holder 104b and a sidewall spacer 105b formed on sidewalls thereof, the same criteria apply as are referred to with respect to the corresponding components 104a and 105a.

A typical process flow for forming the semiconductor device 100 as shown in FIG. 1a may comprise the following processes. After forming the substrate 101 including the semiconductor layer 102 or receiving the same from substrate manufacturers, implantation sequences may be performed to establish a specified vertical dopant profile within the first and second semiconductor regions 107a, 107b. Thereafter, the first and second place holders 104a, 104b may be formed by well-established deposition, photolithography and etch techniques, wherein a length of the first and second place holders 104a, 104b, that is, the horizontal dimension (or gate length dimension) of these components in FIG. 1a, may be adapted to design requirements and may be approximately 100 nm and significantly less for highly advanced integrated circuits. Thereafter, dopant species may be introduced to form the doped regions 106a, 106b therein. Depending on device requirements, the device 100 may correspondingly be masked, for instance by a photoresist mask, to individually form the regions 106a, 106b with a desired type of dopant material. During these implantations, the place holders 104a, 104b act as an implantation mask to substantially avoid dopant penetration of the respective semiconductor regions 107a, 107b. Thereafter, the sidewall spacers 105a, 105b may be formed by depositing a corresponding layer of material and anisotropically etching the material layer. It should be appreciated that, typically, a liner material may be deposited prior to a spacer material so as to not unduly damage the surface of the semiconductor layer 102 when exposed to the anisotropic etch atmosphere. For convenience, a corresponding liner is not shown in FIG. 1a. Then, a further implantation process may be performed, possibly on the basis of a further photoresist mask, wherein also the first and second place holders 104a, 104b in combination with the respective sidewall spacers 105a, 105b act as an implantation mask to obtain the desired lateral dopant profile in the doped regions 106a, 106b, respectively. Then, corresponding anneal cycles may be performed to activate the dopants in the regions 106a, 106b and re-crystallize damaged crystal portions. Alternatively, corresponding anneal processes may be performed after one or more of the above-described implantations.

It should be noted that in some examples when a highly sophisticated lateral dopant profile is required, additional sidewall spacers (not shown) may be formed, followed by a further implantation step to obtain a more complex dopant profile within the regions 106a, 106b. Thereafter, in particular embodiments, the sidewall spacers 105a, 105b may be removed by a selective etch process on the basis of well-established process recipes. For instance, the spacers 105a, 105b, when comprised of silicon nitride, may selectively be removed by hot phosphoric acid. In other examples, the spacers 105a, 105b may be removed by a plasma etch process, wherein, in some embodiments, the liner (not shown), typically used as an etch stop layer, may be maintained during the implantation cycle and may now be used as an etch stop layer during the removal of the spacers 105a, 105b. In other embodiments, the spacers 105a, 105b may be maintained during the further processing of the device 100.

FIG. 1b schematically shows the device 100 in an advanced manufacturing stage. Here, the device 100 comprises a dielectric layer 108 having a specified intrinsic stress, which is formed to enclose the first and second place holders 104a, 104b. The term “intrinsic stress” is to be understood as specifying a certain type of stress, that is tensile or compressive, or any variation thereof, i.e., orientation dependent tensile or compressive stress, as well as the magnitude of the stress. Thus, in one embodiment, the dielectric layer 108 may have an intrinsic tensile stress with a magnitude of approximately 0.1-1.0 GPa (Giga-Pascal). The dielectric layer 108 may be comprised of any appropriate material, such as silicon nitride. In one illustrative embodiment, the device 100 further comprises a conformal etch stop layer 109 having a different material composition compared to the dielectric layer 108 and having a significantly smaller thickness compared to the dielectric layer 108. For example, the etch stop layer 109 may be comprised of silicon dioxide.

The etch stop layer 109, if provided, may be formed by well-established plasma enhanced chemical vapor deposition (PECVD) techniques on the basis of precursor materials, such as TEOS or silane. The dielectric layer 108 may be formed by PECVD techniques on the basis of well-known process recipes, wherein process parameters may be adjusted to achieve the desired intrinsic stress. For example, silicon nitride may be deposited with high compressive or tensile stress, wherein the type and magnitude of the stress may readily be adjusted by controlling process parameters, such as deposition temperature, deposition pressure, tool configuration, bias power for adjusting an ion bombardment during the deposition process, plasma power, and the like. For example, increased ion bombardment, that is increased bias power, during the deposition of silicon nitride promotes the creation of compressive stress given that the remaining parameters are the same. After the deposition of the dielectric layer 108, in some particular embodiments, the resulting topography may be planarized, for instance by chemical mechanical polishing (CMP) in accordance with well-established process recipes. Thereby, excess material of the dielectric layer 108 may be removed to a specified degree to arrive at a substantially planar surface or, in some illustrative embodiments, the material removal may be continued until top surfaces of the first and second place holders 104a, 104b are exposed. In other embodiments, however, the further processing may be performed without planarizing the layer 108.

FIG. 1c schematically shows the device 100 in a further advanced manufacturing stage, in which a portion of the layer 108, which has surrounded the second place holder 104b, is removed while the first place holder 104a is still embedded, at least laterally, by the remaining dielectric layer 108, which is now referred to as 108a. Furthermore, a resist mask 110 is formed on the device 100 to expose the second place holder 104b and the associated portion of the layer 102 including the etch stop layer 109, if provided.

The resist mask 110 may be formed in accordance with photolithography techniques that may also be used in differently doping P-type and N-type transistors and hence corresponding processes are well established. Thereafter, the dielectric layer 108 may selectively be etched by an anisotropic process recipe to finally obtain the dielectric layer 108a having the specified intrinsic stress. During the anisotropic etch process, the etch stop layer 109, if provided, may prevent undue material removal and/or damage of exposed portions of the semiconductor layer 102.

FIG. 1d schematically shows the device 100 with a second dielectric layer 111 having a second specified intrinsic stress, which covers the dielectric layer portion 108a and the second place holder 104b and the exposed semiconductor layer 102 or the etch stop layer 109. It should be noted that the exposed portion of the etch stop layer 109 may be removed prior to the deposition of the second dielectric layer 111, when the exposed portion of the etch stop layer 109 is considered inappropriate owing to any damage caused by the preceding anisotropic etch process of the dielectric layer 108. In this case, a further etch stop layer similar to the layer 109 may be deposited, which may then also cover the dielectric layer portion 108a (shown in dashed lines) and may cover the exposed portions of the semiconductor layer 102 and the second place holder 104b. For convenience, this portion of the etch stop layer is still denoted as 109. Providing the etch stop layer 109 on the semiconductor layer 102 may be advantageous in forming contact openings in a later manufacturing stage. In other embodiments, however, the etch stop layer 109 may be omitted.

The second dielectric layer 111, which may be comprised of any appropriate material, such as silicon nitride, may be deposited by well-established deposition recipes, wherein process parameters are controlled to provide the desired intrinsic stress in accordance with device requirements. As previously noted, silicon nitride may readily be deposited on the basis of well-known process recipes with a wide range of compressive and tensile stress, for example reaching from 1.0 GPa compressive stress to 1.0 GPa tensile stress. In one particular embodiment, the intrinsic stress of the second dielectric layer 111 is designed to impart a compressive stress to the second semiconductor region 107b, when this region is to represent the channel region of a P-type transistor. Thereafter, excess material of the dielectric layer 111 and possibly of the layer portion 108a, when the dielectric layer 108 has not been planarized or has been planarized to a level well above the first place holder 104a, as shown in FIG. 1c and 1d, may be removed by a CMP process, thereby also planarizing the topography of the device 100.

FIG. 1e schematically shows the device 100 after the above-described process sequence. Hence, the device 100 comprises a substantially planar topography with the layer portion 108a laterally enclosing the first place holder 104a and with a second layer portion 111b laterally enclosing the second place holder 104b. Consequently, a substantially homogeneously acting intrinsic stress of the layer portion 108a, herein shown as a tensile stress indicated as 118a, creates a respective deformation and thus strain in the first semiconductor region 107a, that is, in the present example a tensile strain, which typically increases the mobility of electrons in this region. Similarly, the layer portion 111b having the substantially homogeneously acting second intrinsic stress, in this example illustrated in the form of a compressive stress 121b, correspondingly creates a deformation or strain within the second semiconductor region 107b, which is in the present example a compressive strain, thereby increasing the mobility of holes. It should be appreciated that other configurations may be contemplated for creating different strain in the semiconductor regions 107a, 107b. For example, the intrinsic stress 118a may be compressive and the intrinsic stress 121b may be tensile, or the intrinsic stresses 118a and 121b may both be tensile or compressive and may differ in their magnitudes. In other examples, the intrinsic stress 118a or 121b may be selected to yield a substantially zero strain in the respective semiconductor region, whereas the other semiconductor region receives a desired magnitude of strain. This configuration may be advantageous in providing more uniform electrical characteristics of P-type transistors and N-type transistors, wherein the mobility of the P-type transistors is to be increased, while the performance of the N-type transistors should not be deteriorated.

FIG. 1f schematically shows the device 100 with the place holders 104a, 104b removed. Furthermore, respective gate insulation layers 113a, 113b are formed above the first and second semiconductor regions 107a, 107b, respectively.

The removal of the place holders 104a, 104b may be accomplished by a selective etch process, which may include a plasma etch process and/or a wet chemical etch process. For instance, the place holders 104a, 104b when comprised of silicon dioxide or amorphous carbon, may readily be selectively etched with respect to the layer portions 108a, 111b when for instance comprised of silicon nitride, and with respect to the material of the first and second semiconductor regions 107a, 107b on the basis of well-established process recipes. For example, the removal process may include a plasma etch process for selectively removing the essential amount of the first and second place holders 104a, 104b, while the remaining portion of these place holders may then be removed by a highly isotropic or wet chemical etch process so as to not unduly damage the regions 107a, 107b. In other embodiments, additionally or alternatively, damaged surface portions of the regions 107a, 107b may be oxidized, for instance by thermal oxidation or wet chemical oxidation, and the oxidized portion may be removed by a highly selective wet chemical etch process, for instance, on the basis of fluoric acid (HF) without significantly damaging the regions 107a, 107b.

After removing the place holders 104a, 104b, the gate insulation layers 113a, 113b may be formed by oxidation and/or deposition in accordance with design requirements. For example, the gate insulation layers 113a, 113b may be formed by thermal or wet chemical oxidation in accordance with well-established recipes to obtain a finely tuned layer thickness as required for advanced transistor devices. Thereby, a thickness of the gate insulation layer may range from 1.5 to several nanometers. In other embodiments, an extremely thin thermal oxide may be formed, followed by the deposition of an appropriate dielectric material to achieve the desired final thickness of the gate insulation layers 113a, 113b. A corresponding deposited layer is shown in dashed lines and is indicated as 112. It should be appreciated that the gate insulation layers 113a, 113b may also be formed by means of the deposited layer 112 only. In some illustrative embodiments, prior to the formation of the gate insulation layers 113a, 113b, a dielectric layer such as the layer 112 may be deposited in a highly conformal fashion and with a precisely defined layer thickness, when the initial length 112a of the opening defined by the place holder 104a is considered too great for a desired value of the gate electrode to be formed. Thereafter, the material deposited at the bottom of this opening, i.e., on the region 107a, may be removed by an anisotropic etch process, similarly as is used in typical sidewall spacer techniques. In this way, the gate length of transistor structures may be fine-tuned to compensate for fluctuations in the photolithography or to extend the resolution of the photolithography. Thereafter, the respective gate insulation layers may be formed as is described above.

FIG. 1g schematically shows the semiconductor device 100 with a layer of conductive material 123 formed above the structure of FIG. 1f. The layer 123 may be comprised of doped polysilicon or, in embodiments for highly advanced semiconductor devices, may comprise a metal or a metal compound. For example, the layer 123 may comprise tungsten, tungsten silicide, aluminum, nickel, copper, or any compounds thereof, and the like. Depending on the type of material used for the layer 123, corresponding deposition techniques may be used. For instance, polysilicon, aluminum, tungsten, tungsten silicide, and the like may readily be deposited on the basis of well-established chemical vapor deposition (CVD) techniques. In other cases, plating methods such as electroplating or electroless plating may be used for reliably filling the respective openings above the first and second semiconductor regions 107a, 107b. Thereafter, any excess material of the layer 123 may be removed by any appropriate technique, such as etching, chemical mechanical polishing, and any combination thereof.

FIG. 1h schematically shows the semiconductor device 100 with the excess material of the layer 123 removed and with a further interlayer dielectric 126 formed as the uppermost layer of the resulting structure. Thus, the device 100 comprises a gate electrode structure 124a above the first semiconductor region 107a and a second gate electrode structure 124b above the second semiconductor region 107b, thereby defining a first transistor element 130a and a second transistor element 130b. Moreover, as shown in FIG. 1h, the layer portion 108a provides the first intrinsic stress 118a acting substantially homogeneously on the gate electrode structure 124a up to a height 125a, whereas the second layer portion 111b provides the second intrinsic stress 121b that acts substantially homogeneously on the second gate electrode structure 124b up to a height 125b thereof. Consequently, depending on the stresses 118a, 121b, respective deformations or strains are achieved in the associated semiconductor regions or channel regions 107a, 107b. Hence, the charge carrier mobility in these channel regions is individually adjustable by correspondingly controlling the stress 118a, 121b. In particular, the transistor configuration as shown in FIG. 1h is substantially planar and enables a self-aligned formation of the doped regions 106a, 106b, i.e., the respective drain and source regions, with respect to the associated gate electrode structures 124a, 124b. Moreover, the gate electrode structures 124a, 124b may be formed of a highly conductive material, such as a metal, metal compound, highly doped polysilicon, or any combination thereof, and the like. In particular embodiments, the gate electrode structures 124a, 124b are substantially comprised of a metal.

FIG. 2 schematically shows a semiconductor device 200 in an intermediate manufacturing stage in accordance with further illustrative embodiments of the present invention. In FIG. 2, identical or similar components as are shown in FIGS. 1d and 1e are denoted by the same reference signs except for a leading “2” instead of a “1.” Hence, the device 200 comprises the substrate 201 with the semiconductor layer 202 formed thereon including the first and second semiconductor regions 207a, 207b with the associated doped regions 206a, 206b. The place holders 204a, 204b are laterally embedded into the dielectric layer 208 having a specified intrinsic stress. Moreover, the resist mask 210 is formed above the dielectric layer 208 to expose that portion of the device 200 that is associated with the second semiconductor region 207b. Regarding the formation of the device 200 as shown in FIG. 2, it is referred to the description with reference to FIGS. 1a, 1b and 1c.

Moreover, the device 200 is subjected to an ion bombardment 240 to modify the stress characteristics of a layer portion 208b of the dielectric layer 208, which is not covered by the resist mask 210. For example, heavy inert ions, such as xenon, argon, silicon, and the like, may be implanted into the portion 208b, thereby relaxing, at least partially, the specified intrinsic stress. Consequently, the layer portion 208a maintains the specified intrinsic stress, thereby creating a specified deformation within the first semiconductor region 207a, while the corresponding strain in the second semiconductor region 207b may significantly differ therefrom, depending on the degree of relaxation within the layer portion 208b. For example, the dielectric layer 208 may have been deposited with a high compressive stress, for instance when the regions 206a, 207a are to represent a P-type transistor configuration, to significantly improve the hole mobility in the first semiconductor region 207a. By relaxing the initially compressive stress in the layer portion 208b to a specified degree, the amount of reduction of electron mobility within the second semiconductor region 207b, when designed as an N-type channel region, may then be adjusted in accordance with design requirements. As already previously stated, the first and second semiconductor regions 207a, 207b may not necessarily need to represent different types of channel regions but may also represent identical channel regions, wherein for instance a different degree of operational behavior or a desired degree for adjustment of device uniformity may be achieved by the process technique as shown in FIG. 2.

The further processing of the device 200 may then be continued as is also described with reference to the device 100 depicted in FIG. 1e-1h.

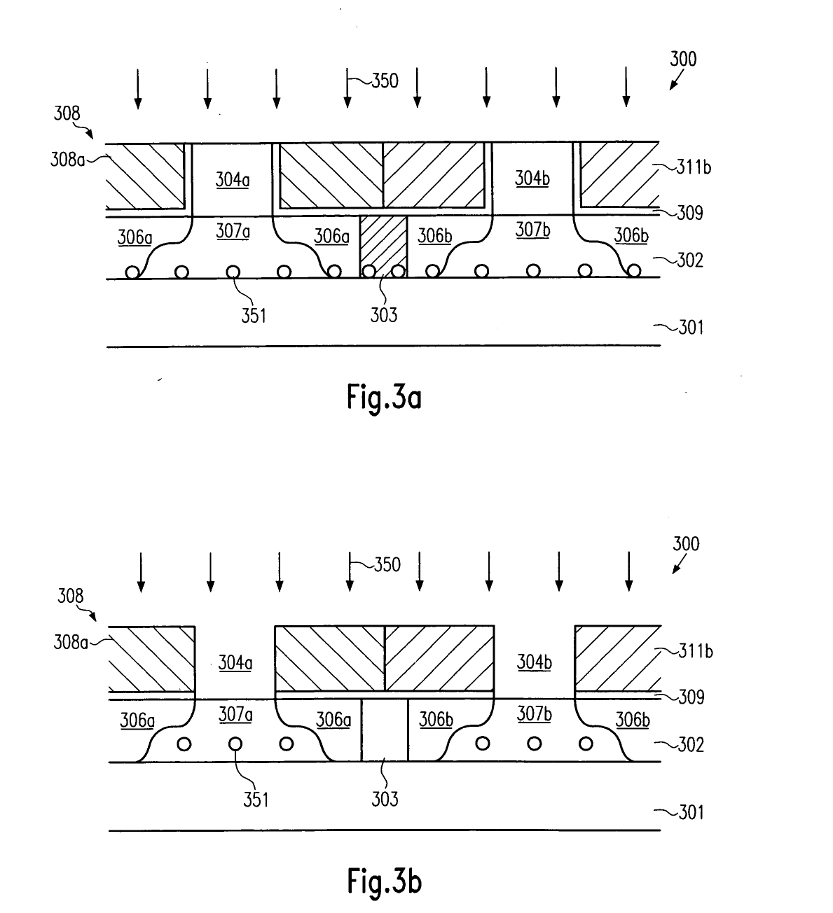

FIG. 3a schematically shows a semiconductor device 300 in accordance with further illustrative embodiments of the present invention. The device 300 may represent a device similar to that shown in FIG. 1e so that similar or identical components are denoted by the same reference numbers except for a leading “3” instead of a “1.” Thus, a detailed description of these components is omitted here. Moreover, the device 300 is subjected to an ion implantation 350 for inserting a light ion species, such as hydrogen, helium or oxygen, into the semiconductor layer 302 or the substrate 301. The ion implantation 350 is performed with a high dose and an appropriate energy to achieve a high impurity concentration at a desired depth within the layer 302 and/or the substrate 301. For example, initially implanted peak concentration may be selected to achieve a concentration in the range of approximately 10²¹-10²³ atoms/cm³. Typical implantation parameters for helium or hydrogen may be approximately 3-15 keV, depending on the desired penetration depth with a dose of approximately 5×10¹⁵ to 2×10¹⁶ ions per cm². Thereafter, a heat treatment may be performed, for instance at temperatures of approximately 350-1,000° C. and typically at approximately 700-950° C. for a time period of several minutes to create “bubbles” or “voids” 351 within the layer 302 and/or the substrate 301. Since the ion implantation 350 is performed through the layer portions 308a, 311b with the place holders 304a, 304b still being present, a substantially uniform depth for the bubbles 351 is achieved. Since a light inert species is introduced, the stop mechanism during the implantation is mainly based on an interaction with crystal electrons so that damage in the layers 308a, 311b and thus stress relaxation is negligible. Due to the bubbles 351, a certain degree of mechanical decoupling of the regions 306a, 307a, 306b, 307b from the remaining layer 302 and/or the substrate 301 is achieved, thereby significantly enhancing the transfer of stress from the layer portions 308a, 311b into the respective regions 307a, 307b. Thus, the strain engineering of the regions 307a, 307b may significantly be enhanced and thus the charge carrier mobility and the channel conductivity may be improved more efficiently.

It should be appreciated that in other embodiments the ion implantation 350 may be performed at an earlier manufacturing stage, for instance prior to the formation of the layer portions 308a, 311b and possibly prior to the formation of the place holders 304a, 304b, thereby avoiding any relaxation effects, even though they may be very small as explained above. The bubbles 351 may then be created during any anneal cycles for activating the dopants in the region 306a, 306b.

FIG. 3b schematically shows the semiconductor device 300, in which the place holders 304a, 304b are removed prior to the ion implantation 350. In this case, the implantation energy may be selected to position the light ion species within the semiconductor layer 302 substantially without affecting the regions 306a, 306b. Hence, the semiconductor regions 307a, 307b may highly efficiently be decoupled from the remaining semiconductor layer 302 by means of the bubbles 351. Thus, the stress transferred to the regions 307a, 307b is also significantly increased. Moreover, the bubbles 351 themselves may act as a source of stress, thereby also creating a corresponding strain within the respective regions 307a, 307b. In this way, two effective strain-inducing mechanisms may be combined.

As a result, the present invention provides a semiconductor device and a technique for forming the same wherein different semiconductor regions may receive a different strain, while the formation process allows the formation of planar transistor architectures including highly conductive gate electrodes. For this purpose, a dielectric layer laterally enclosing the gate electrode structures of various transistor elements is locally modified such that at least two different strain components are obtained in the respective channel regions. Thus, complementary transistor pairs may be formed, each transistor having a differently strained channel region. The modification of the strain-inducing stress layer may be accomplished by removing a specified portion of the layer and replacing it with a layer portion of a different intrinsic stress and/or by relaxing the intrinsic stress to a desired degree. Furthermore, due to the combination of the enhanced stress or strain engineering technique with a process for in-laid gate electrode structures, extremely highly conductive gate electrode structures may be attained, thereby providing enhanced gate and channel conductivity even for extremely scaled devices having a gate length of 100 nm and significantly less. Additionally, the local stress modification may advantageously be combined with mechanisms for effectively decoupling the channel regions from the surrounding material, thereby remarkably enhancing the efficiency of stress transfer into the respective channel regions.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first place holder structure above a first semiconductor region formed in a semiconductor layer located on a substrate;
forming a second place holder structure above a second semiconductor region formed in said semiconductor layer;
depositing a dielectric layer having a specified intrinsic stress above said semiconductor layer to enclose said first and second place holder structures;
modifying a portion of said dielectric layer enclosing said second place holder structure to change said intrinsic stress of said portion; and
replacing said first and second place holder structures with a conductive material.

2. The method of claim 1, further comprising forming doped regions in said semiconductor layer adjacent to said first and second semiconductor regions.

3. The method of claim 2, wherein forming said doped regions comprises introducing at least one dopant species by an ion implantation process while using said first and second place holder structures as an implantation mask.

4. The method of claim 3, wherein forming said doped regions comprises introducing a first dopant species of a first conductivity type adjacent to said first place holder structure and introducing a second dopant species of a second conductivity type adjacent to said second place holder structure to form doped regions of a first conductivity type adjacent to said first place holder structure and doped regions of a second conductivity type adjacent to said second place holder structure.

5. The method of claim 3, wherein forming said doped regions comprises forming at least one sidewall spacer element on sidewalls of each of said first and second place holder structures and using said at least one sidewall spacer as an implantation mask at least during one step of said ion implantation process.

6. The method of claim 5, further comprising removing said at least one sidewall spacer prior to depositing said dielectric layer.

7. The method of claim 1, wherein modifying said portion surrounding said second place holder structure comprises removing said portion.

8. The method of claim 7, further comprising depositing a second dielectric layer above said semiconductor layer, said second dielectric layer having a second intrinsic stress that differs from the intrinsic stress of said dielectric layer.

9. The method of claim 8, further comprising removing material of said second dielectric layer to expose a top surface of said second place holder structure.

10. The method of claim 7, further comprising planarizing a surface of said dielectric layer prior to removing said portion surrounding said second place holder structure.

11. The method of claim 1, further comprising depositing an etch stop layer prior to depositing said dielectric layer.

12. The method of claim 1, wherein modifying said portion surrounding said second place holder structure comprises selectively relaxing said intrinsic stress in said portion.

13. The method of claim 12, wherein said intrinsic stress is selectively relaxed by ion bombardment of said portion.

14. The method of claim 1, further comprising implanting an inert species into an area adjacent to at least one of said first semiconductor region and said second semiconductor region and heat treating said substrate to form voids caused by said inert species.

15. The method of claim 14, wherein said inert species is implanted prior to replacing said first and second place holder structures.

16. The method of claim 14, wherein said inert species is implanted as an intermediate step of said act of replacing said first and second place holder structures.

17. A method, comprising:
forming a first place holder structure above a first channel region of a first transistor;
forming a second place holder structure above a second channel region of a second transistor;
forming first drain and source regions adjacent to said first channel region;
forming second drain and source regions adjacent to said second channel region;
forming above said first drain and source regions a first dielectric layer having a first intrinsic stress;
forming above said second drain and source regions a second dielectric layer having a second intrinsic stress that differs from said first intrinsic stress; and
replacing said first place holder structure with a first gate electrode structure and said second place holder structure with a second gate electrode structure.

18. The method of claim 17, wherein forming said second dielectric layer comprises forming said first dielectric layer above said second drain and source regions, selectively removing at least a portion of said first dielectric layer above said second drain and source regions, depositing dielectric material having intrinsic stress that differs from said first intrinsic stress and planarizing a structure resulting from the deposition of said dielectric material.

19. The method of claim 17, wherein forming said dielectric layer comprises depositing said first dielectric layer above said second drain and source regions and modifying said first dielectric layer above said second drain and source regions to form said second dielectric layer.

20. The method of claim 19, wherein modifying said first dielectric layer above said second drain and source regions comprises a selective ion bombardment process.

21. The method of claim 17, wherein said first drain and source regions are N-doped and said second drain and source regions are P-doped.

22. The method of claim 21, wherein said first intrinsic stress is tensile.

23. The method of claim 21, wherein said second intrinsic stress is compressive.

24. The method of claim 21, wherein said first intrinsic stress is tensile and said second intrinsic stress is compressive.

25. The method of claim 17, wherein replacing said first and second place holder structures by first and second gate electrode structures comprises selectively removing said first and second place holder structures, forming a first gate insulation layer on said first channel region and forming a second gate insulation layer on said second channel region and depositing a conductive material.

26. The method of claim 25, wherein depositing said conductive material comprises depositing a metal-containing material.

27. A semiconductor device, comprising:
a first transistor element having a first gate electrode with a first height;
a second transistor element having a second gate electrode with a second height;
a first dielectric layer having a first intrinsic stress and laterally enclosing said first gate electrode, said first intrinsic stress acting substantially homogeneously up to said first height; and
a second dielectric layer having a second intrinsic stress and laterally enclosing said second gate electrode, said second intrinsic stress differing from said first intrinsic stress and acting substantially homogeneously up to said second height.

28. The semiconductor device of claim 27, wherein a length of at least one of said first and second gate electrodes is approximately 100 nm and less.

29. The semiconductor device of claim 28, wherein said gate electrode is formed of a metal.

30. The semiconductor device of claim 27, wherein said second transistor is a P-type transistor and said second intrinsic stress is compressive.

31. The semiconductor device of claim 30, wherein said first transistor element is an N-type transistor and said first intrinsic stress is tensile.
